(19) United States
(12) Patent Application Publication
(10) Pub. No.: US 2011/0075871 A1
(43) Pub. Date: Mar. 31, 2011

(54) Soft Concha Ring In-The-Ear Hearing Aid

(75) Inventors: Robert J. Fretz, Maplewood, MN (US); Derek Pfeffer, Robbinsdale, MN (US)

(73) Assignee: INTRICON CORPORATION, Arden Hills, MN (US)

(21) Appl. No.: 12/895,012

(22) Filed: Sep. 30, 2010

Related U.S. Application Data
(60) Provisional application No. 61/247,303, filed on Sep. 30, 2009.

(51) Int. Cl. H04R 25/00; H05K 13/00; B23P 19/00

(52) U.S. Cl. 381/321; 29/592.1; 29/428

(57) ABSTRACT

A hearing aid has a suspension portion received in the wearer's concha bowl and an electronics portion. The suspension portion is formed of a flexible rubbery material, while the electronics portion includes a shell formed of a rigid plastic material. The suspension portion is provided as a ring having an annulus, and bears off a tragus contact area, an antitragus contact area and an antihelix contact area to support the receiver in a suspended, cantilevered position within the ear canal. The microphone can be within the flexible ring housing portion. The hearing aid makes much more comfortable contact with the concha bowl.

### CROSS-REFERENCE TO RELATED APPLICATION(S)

The present application claims priority from U.S. Provisional Application No. 61/247,303 entitled SOFT CONCHA RING IN-THE-EAR HEARING AID, filed Sep. 30, 2010, incorporated herein by reference.

### BACKGROUND OF THE INVENTION

The present invention relates to hearing aids. In particular, the present invention pertains to the physical structure used to mount and assemble hearing aid electronic components for wearing in or on the ear of a user.

Hearing aids are electrical devices having a microphone to receive sound and convert the sound waves into an electrical signal, some sort of amplification electronics, and a speaker (commonly called a “receiver” in the hearing aid industry) for converting the amplified electronic signal back into sound waves that can be better heard by the user. The electronic circuitry is commonly powered by a replaceable battery.

Over the years, great advances have been made in the electronic circuitry. It is now common to have the amplification electronics performed in a digital (rather than analog) realm with a programmable digital signal processor (“DSP”) chip. Of course, with a DSP chip, an analog-to-digital converter must be present either in the microphone, the DSP chip or as a separate component between the microphone and the DSP chip, and a digital-to-analog converter must be present either in the DSP chip, the receiver, or as a separate component between the DSP chip and the receiver. With today's DSP chips, the hearing aid can be easily programmed so its sound output is not identical to the sound input, but rather is specially customized for the hearing deficiency of a particular user. Today's DSP chips can also be easily programmed to have differing amplification modes, such as having a different transfer function used in a music concert than in a crowded restaurant. The size of the electronics has greatly decreased over the years, permitting a large variety of different hearing aid styles for mounting and supporting the electronic functions. For a given complexity, the cost of the electronics has also greatly decreased over the years.

Despite the great advances in hearing aid electronics, hearing aids are not universally worn by all who have some sort of hearing deficiency—far from it. It turns out that the actual programmable signal gain in the hearing aid is only a small part of the consumer's decision. In addition to how the hearing aid sounds, users are concerned with how the hearing aid looks, and with how the hearing aid feels. Many users want hearing aids which are as inconspicuous as possible. The hearing aid must fit comfortably, preferably remaining comfortable in a wide variety of conditions (differing health conditions of the wearer, changes in weather, changes in altitude, changes in headgear, etc.). Additionally, the fit of the hearing aid can affect the electronic performance, particularly in feedback modes in conditions when the amplified sound from the receiver is acoustically received by the microphone in a resonant frequency, with the feed forward electronic gain exceeding the acoustic attenuation of the feedback sound. The wide variety of physical wearing conditions affects the acoustic feedback transfer function of the hearing aid, and hearing aids often produce undesirable crackles and whistles during particular and difficult to predict acoustic and physical events. The great advances in hearing aid electronics have not nearly succeeded in universal adoption of hearing aids by all who could benefit.

Many different physical styles of hearing aids have developed seeking to take best advantage of the advances in hearing aid electronics. While hearing aids were initially often bulky and body worn (in a shirt pocket, on spectacles, etc.), today most hearing aids are worn and supported entirely by a single ear of the wearer. Some hearing aids have the primary electronics Behind-The-Ear (“BTE”), with most BTE designs having an acoustic tube which is mounted from a BTE receiver into the ear canal. The acoustic tube is secured in the canal by any of a variety of tips, with some of the tips being hard plastic custom shapes, and other tips being standard sizes with some flexibility. Another type of hearing aid, In-The-Ear (“ITE”) hearing aids are constructed of hard plastic that fits into the user's ear canal, with the primary electronics filling the user's ear bowl, called the concha. Even smaller devices, In-the-Canal (“ITC”) and Completely-In-the Canal (“CIC”) hearing aids, are also made of hard plastic and fit largely or entirely into the user's ear canal. Receiver-In-The-Ear (“RITE”) or Receiver-In-Canal (“RIC”) devices position most of the electronics behind the ear and then have a flexible tube with a wire leading to a receiver positioned within the ear canal.

With the exception of the very flexible tubes, hard plastic such as acrylic is most often used to hold the electronics and wiring stable. For ITC and CIC devices particularly, the hard plastic shells may be custom shaped to fit the particular shape of the user's ear canal, but custom shaping is expensive and time consuming in the fitting of a hearing aid.

For some ITE or ITC models, a resilient element such as a spring can be used to bias off anatomical structures in the user's outer ear, generally to push the hearing aid shell into tighter contact with the ear canal and perhaps simultaneously provide an out-of-the-canal structure used to pull the hearing aid out of the ear canal. Resilient or soft materials are also frequently used to make a more comfortable or tighter contact within the user's ear canal, such as a soft covering on the hard plastic shell to reduce the pressure points pressing against the user's ear canal.

There are weaknesses of all these various designs. BTE and ITE styles are not as discrete in appearance as many users would like. For CICs and ITCs, one-size-fits-most housings are difficult to make comfortable since ear canals have a large variety of shapes and the thin skin over bone and the hard plastic results in sensitivity to any misfits. Another problem is that the microphone location, especially for CICs and ITCs, is near the speaker output. This results in very high feedback. The most common method to attempt to reduce feedback is for the ear canal to be as occluded as possible to reduce the acoustic feedback from the receiver to the microphone. Feedback cancellation algorithms available in modern hearing aid amplifiers help somewhat, but are usually unable to prevent oscillation without the help of some physical blocking of the ear canal. However, physical blocking of the ear canal often reduces comfort of the wearer, at least in some situations (having a cold, riding an elevator, etc.). RITE, RIC and acoustic tube designs also have essentially two different insertion steps, one positioning and attaching the hearing aid electronics relative to the ear, and a second positioning and/or attaching the tube in the ear canal. The insertion process is particularly a problem for elderly users with dexterity limitations. Consistent fits on a day-to-day basis, requiring identical repositioning of the flexible tube and/or receiver, are hard to achieve.

Separate from the hearing aid field, earplugs and sound protectors have been developed which are intended to occlude the user's ear canal as much as possible. For instance, Surefire LLC of Fountain Valley, Calif. makes a variety of earplugs and communication systems earbuds which are usually intended to block out as much ambient noise as possible by sealing to the ear canal wall. For radio communication models which are intended to permit the passage of ambient sound, a central lumen is formed through the ear canal portion of the device.

Improved physical hearing aid designs could be made to take better advantage of the advances in electronics. The physical hearing aid designs should be as comfortable as possible to the wearer. The physical hearing aid designs should be pleasing visually, such as being as visibly inconspicuous as possible. The design should accommodate a large variety of ear anatomical shapes, allowing for easy insertion and removal. The physical hearing aid designs should also minimize feedback problems.

### BRIEF SUMMARY OF THE INVENTION

The present invention is a hearing aid having a suspension portion received in the wearer's concha bowl. The suspension portion is flexible and bears off a tragus contact area, an antitragus contact area and an antihelix contact area. Based on forces generated from these concha bowl contact areas, the receiver is suspended in a cantilevered position within the ear canal. The flexibility of the suspension portion at the contact areas ensures a comfortable fit. The receiver is commonly supported in a shell housing portion which is formed of a rigid plastic material. The suspension portion is preferably provided by a flexible ring housing portion which is joined to the more rigid shell housing portion. The annulus of the ring housing portion provides an open concha skin surface, which can naturally reflect sound down the generally open ear canal. The hearing aid makes much more comfortable contact with the concha bowl to hold the receiver in its cantilevered, suspended position. In the preferred embodiment, the microphone is within the flexible ring housing portion.

### BRIEF DESCRIPTION OF THE DRAWINGS

FIG. 1 is an elevational side view of common ear anatomy.

FIGS. 2 through 5 are side, bottom and front views of the hearing aid of the present invention.

FIGS. 6-13 are cross-sectional views of the canal portion of the hearing aid of the present invention, taken alone the respectively numbered cut lines in FIGS. 3 and 4.

FIG. 14 is the side view of FIG. 2, with a tetrahedron added to show the lines measured as distances between the tragus contact area, the antitragus contact area and the antihelix contact area of the preferred hearing aid geometry.

While the above-identified drawing figures set forth preferred embodiments, other embodiments of the present invention are also contemplated, some of which are noted in the discussion. In all cases, this disclosure presents the illustrated embodiments of the present invention by way of representation and not limitation. Numerous other minor modifications and embodiments can be devised by those skilled in the art which fall within the scope and spirit of the principles of this invention.

### DETAILED DESCRIPTION

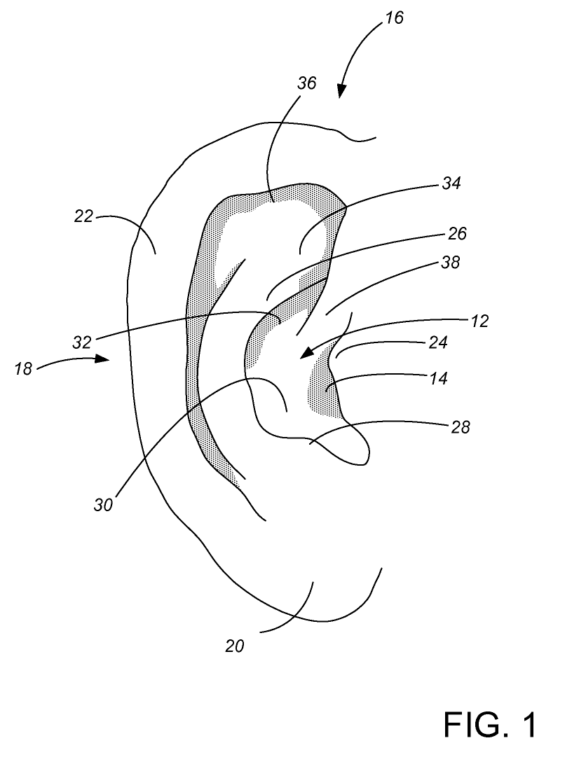

The present invention is an ITE hearing aid 10 which fits within the concha bowl 12 and ear canal 14 of a user's ear 16. While external ear anatomy is somewhat complex and can differ greatly from person to person, FIG. 1 depicts and identifies well-known external ear anatomy which is commonly shared among the vast majority of people. The human ear 16 includes a broad outer structure (called the pinna 18) including the ear lobe 20 (lobulus) and the helix 22. The ear canal 14 is partly obscured by the tragus 24. The concha bowl 12 lies between the ear canal 14 and the antihelix 26, with the antitragus 28 and the antihelix 26 slightly obscuring the edge of the concha bowl 12. The concha bowl 12 includes a lower portion known as the cavum conchae 30 and an upper portion known as the cimba conchae 32. The antihelix 26 extends around the cimba conchae 32 to a top portion known as the crus inferius antehelicis 34, and the helix 22 extends forwardly around the crus antehelicis 36 to just above the ear canal 14 terminating in the radix helices 38. The ear drum and other internal ear structure reside well down the ear canal 14. In an average adult, the ear canal 14 is about 26 mm long, with its central axis at a slightly forward angle to the plane generally established by the pinna 18 and concha 12, and with the central axis curving slightly. The ear canal shape (cross-sectional to its central axis) is largely circular or ovular, with an average cross section dimension (diameter) decreasing from about 9 to 7 mm.

Generally speaking, ITC and CIC hearing aid bodies reside within the ear canal 14 and maintain their position within the ear 16 by a frictional or compressive fit with the wall of the ear canal 14. ITE hearing aid body structures, in contrast, reside primarily within the concha bowl 12. Within the human population, the concha bowl 12 has much less variation in shape than ear canals 14. However, there is some variation in the concha size. That is, the distance between the tragus 24, antitragus 28 and the top of the antihelix 26 may be greater or smaller from individual to individual, but will maintain a generally consistent ratio, with the direction of the skin faces of the tragus 24, antitragus 28 and antihelix 26 being fairly consistent from person to person. The concha bowl 12, and particularly the side faces of the tragus 24, antitragus 28 and antihelix 26 defining the concha bowl 12, is more tolerant of pressure than the ear canal 14 or other internal ear structures.

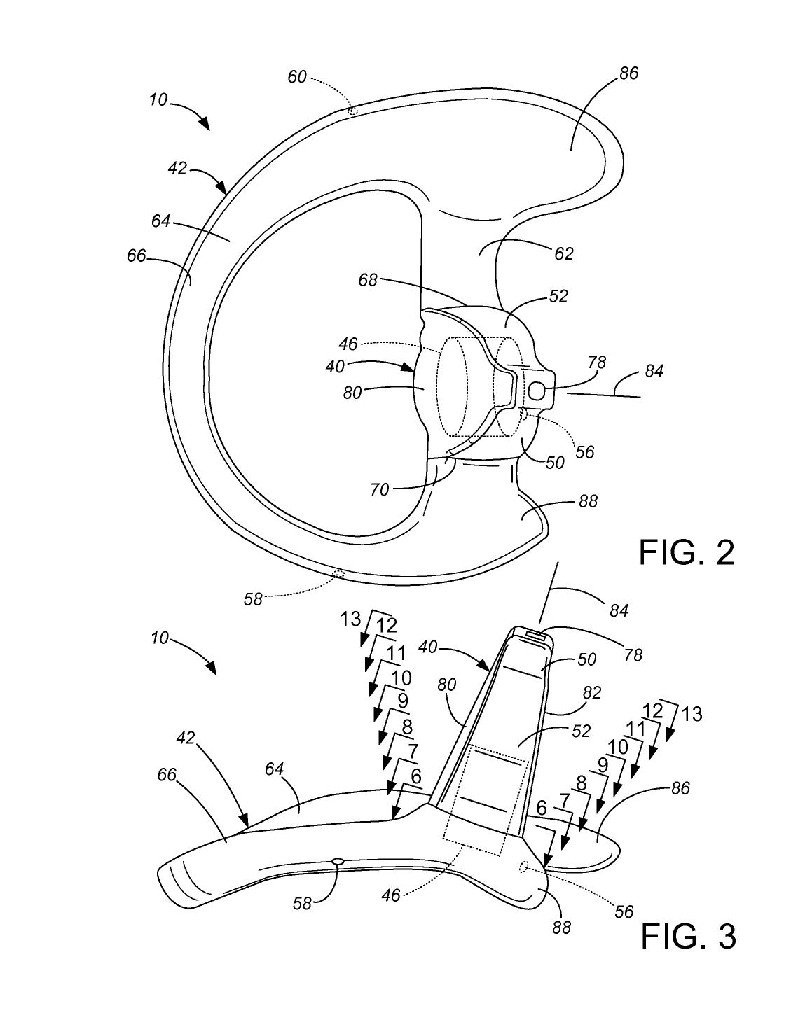

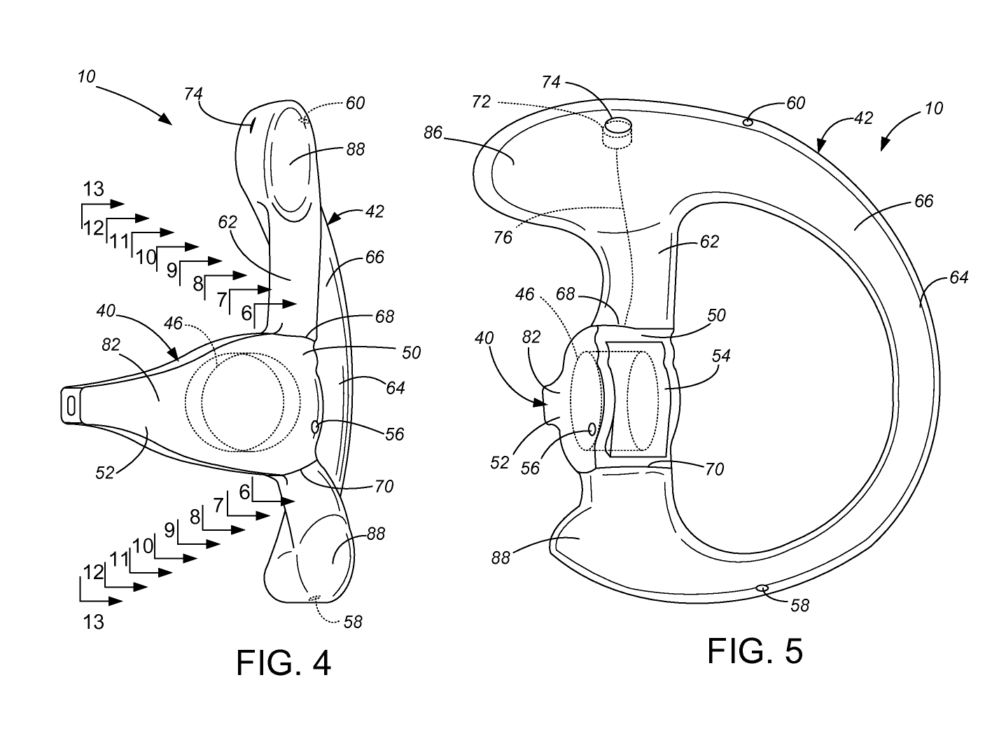

The present invention takes advantage of the more consistent concha bowl shape and higher pressure tolerance to provide a hearing aid 10 which is supported by the concha bowl 12 but which extends in a cantilevering fashion into the ear canal 14. As shown in FIGS. 2-5, the hearing aid 10 includes an electronics portion 40 and a suspension portion 42. The electronics portion 40 houses at least the receiver 44 (shown in FIGS. 12 and 13) and preferably most of the other electrical components including the battery 46 (shown in dashed lines in FIGS. 2-5) and the DSP chip 48 (shown in FIGS. 10 and 11). The electronics portion 40 also houses the electrical connections (not shown in figures) between these electrical components 44, 46, 48. For reference, the battery 46 depicted in the drawings is a conventional size 10 battery, which has a generally cylindrical shape with about a 5.7 mm diameter and a 3.5 mm height. With the current availability of microminiature hearing aid components, the battery 46 is easily the largest electrical component of the hearing aid 10. For instance, the DSP chip 48 may be generally rectangular of about 2.5×3.5×1 mm, and the receiver 44 may be generally rectangular of about 5×2×2 mm.

The electronics portion 40 includes a housing 50 which has a shell 52 and a battery door 54 (only visible in FIG. 5) hinged to the shell 52. The battery door 54 typically carries the battery 46 and can be pivoted to an open position for replacement of the battery 46. In its preferred form, the housing 50 of the electronics portion 40 is formed separately from the suspension portion 42. For instance, the shell 52 (including its face plate if using a face plate assembly method) and the battery door 54 may both be molded from a polymer material such as acrylic, or any other traditional bio-compatible plastic material commonly used for hearing aid housings. Such traditional hearing aid plastics typically have a durometer of greater than about 50 on the Shore D scale.

While the durometer of the plastic material of the shell 52 and battery door 54 is important, more significant is the relative stiffness of the material during use of the hearing aid 10, which is a function of durometer, shear strength, and geometry such as wall thickness. The shell 52 and the battery door 54 are both formed with sufficient wall thicknesses and geometry so as to be dimensionally stable during use and operation of the hearing aid 10. That is, since the purpose of the shell 52 and battery door 54 is primarily to house and protect the electrical connections between the electrical components, the wall thicknesses are chosen to be sufficiently thick that the housing 50 will not substantially compress or deflect if/when in contact with ear canal tissue during insert, removal or use of the hearing aid 10, relative to the compression or deflection of the tissue itself. Typically this will be a material and geometry which provides a stiffness of 1000 N/m or more over the first 0.5 mm of deflection.

The suspension portion 42 of the hearing aid 10 resides within the concha bowl 12 and supports the weight of the hearing aid 10 through compressive forces against the concha skin surfaces. The hearing aid structure of the present invention is not intended to significantly contact or press into the ear canal wall, and to provide the suspension concept of the invention the contact surfaces with the concha bowl 12 must be spread out over a substantial area. Essentially, the suspension portion 42 includes a tragus contact area 56, an antitragus contact area 58 and an antihelix contact area 60 (denoted in FIGS. 2-5), each of which exert a mild compressive force against their corresponding skin surface. A generally vertical rib 62 extends between the tragus contact area 56 and the antihelix contact area 60. An arcuate rib 64 extends between the antitragus contact area 58 and the antihelix contact area 60, such that the suspension portion 42 has an overall shape like a D.

The tragus contact area 56, the antitragus contact area 58 and the antihelix contact area 60 need not have any identifiable marking on the hearing aid 10 to the wearer, but rather are denoted in the drawings merely to explain the operation of the structure within the concha bowl 12. The point of denoting the tragus contact area 56, the antitragus contact area 58 and the antihelix contact area 60 is not to suggest that the suspension portion 42 makes “point contact” with the concha skin or even necessarily makes contact at all at these specific points with any wearer's specific concha anatomy. Instead, the tragus contact area 56, the antitragus contact area 58 and the antihelix contact area 60 each conceptually represent a center point where a mild compressive force is exchanged between the suspension portion 42 and any wearer's concha anatomy. As shown in FIG. 1, the tragus 24, the antitragas 28 and the antihelix 26 all have an undercut that secures each of the tragus contact area 56, the antitragus contact area 58 and the antihelix contact area 60 in place.

The tragus contact area 56, the antitragus contact area 58 and the antihelix contact area 60 jointly define a base plane for the hearing aid 10, with the compressive force from the concha anatomy being generally directed inward in this base plane. The spacing between the tragus contact area 56, the antitragus contact area 58 and the antihelix contact area 60 allow the suspension portion 42 to remain generally stationary relative to the ear 16 even as the wearer accelerates, decelerates and turns his or her head this way and that. Moreover, the spacing between the tragus contact area 56, the antitragus contact area 58 and the antihelix contact area 60 all cause the hearing aid 10 to suspend the receiver 44 (e.g., the apex of the electronics portion 40) in a relatively stationary location within the ear canal 14 without significantly biasing off any wall of the ear canal 14. Much like three spaced legs of a stool can be used to support the seat, the forces from the tragus contact area 56, the antitragus contact area 58 and the antihelix contact area 60 can withstand gravitational and accelerational forces and moments on the cantilevered, suspended receiver 44 (and any other cantilevered structure of the electronics portion 40).

This concept of suspending the receiver 44 centered in the ear canal 14 based off biasing forces from the concha bowl 12 is very different from the bearing concepts of prior art ITE structures, which either leave the receiver 44 substantially outside the ear canal 14 or bias off the ear canal 14. This concept of suspending the receiver 44 centered in the ear canal 14 based off biasing forces from the concha bowl 12 is very different from ITC and CIC structures, which necessarily bias off the ear canal wall. Even with any supporting spring types of structures, the prior art spring concept has generally been to bias the hearing aid 10 into and against the ear canal 14, not to achieve a cantilevered, suspended position for the receiver 44. This concept of suspending the receiver 44 centered in the ear canal 14 based off biasing forces from the concha bowl 12 is also very different from RITE, RIC and acoustic tube structures which have too great of flexibility and require separate positioning and support of the in-the-canal portion of the hearing aid.

In addition to a portion of the shell 52 residing outside the ear canal 14, the preferred suspension portion 42 includes a concha ring structure 66 which is formed separately from the shell 52 and battery door 54. The concha ring structure 66 is made from a generally soft and flexible polymer. For example, the concha ring structure 66 can be formed of a resilient polymer commonly considered a rubbery material, such as having a durometer of less than about 90 on the Shore A scale, with the preferred rubbery material having a Shore A durometer of between 35 and 45, and most preferably a Shore A durometer of approximately 40. The preferred material for the concha ring structure 66 is a translucent PVC material, such as 3019-40/45 Clear 003, an injection-moldable flexible PVC compound with rubber like flexibility and softness available from AlphaGary of Leominster, Mass. This material has a specific gravity of 1.13 (ASTM D 792), a durometer A, 10 Second (⅛″/24 hr) value of 40/45, a durometer A, 10 Second (¼″/24 hr) value of 35/45 (both ASTM D2240), a tensile strength (75 mil) of 1200 psi, an elongation (75 mil) of 525%, and a modulus 100% (75 mil) of 340 psi (all ASTM D 638).

Like the material for the shell 52 and battery door 54, more important than its material properties are the relative flexibility of the concha ring structure 66 relative to the concha anatomy, which is a function of durometer, shear strength, and geometry. Namely, when a mild compressive force is delivered in the base plane for the hearing aid 10 on each of the tragus contact area 56, the antitragus contact area 58 and the antihelix contact area 60, the concha ring structure 66 should substantially compress or deflect relative to the compression or deflection of the tissue itself. Numerically, the present invention should have a geometry and material designed to have a flexibility between the tragus contact area 56, the antitragus contact area 58 and the antihelix contact area 60 of about 200 N/m or less over the first millimeter or two of deflection.

The concha ring structure 66 is joined to the shell 52 at a top junction 68 and at a bottom junction 70, such as with an epoxy adhesive. Alternatively, the shell 52 and the concha ring structure 66 can be formed with a mating attachment configuration, such as a flexible button/rigid loop attachment structure. Alternatively, the concha ring structure could be formed to wrap around the shell 52 either outside the canal or shallowly in the canal. Either way, at least two of the tragus contact area 56, antitragus contact area 58 and antihelix contact area 60 are preferably provided on the concha ring structure 66 so that the suspension portion 42 as a whole allows substantial compression or deflection of the tragus contact area 56, the antitragus contact area 58 and the antihelix contact area 60.

The microphone 72 for the preferred embodiment is in the antihelix area, with a microphone port 74 visible in the view of FIG. 5. Small wires 76 connect the microphone 72 to the electronics portion 40. In the preferred manufacturing method, the concha ring portion 66 is molded and solidified prior to assembly of the microphone 72 therein. The concha ring portion 66 can be cut to provide an opening for the microphone 72, including slitting the concha ring portion 66 where it is desired to run the microphone wires 76. The microphone 72 is then connected to its wires 76, with the microphone 72 and its wires 76 jointly inserted into the opening and slit. Alternatively, a slot could be molded into the concha ring portion 66, with the microphone 72 and its wires 76 then placed into the slot and then the wires 76 (and possibly part of the microphone 72, but leaving an open microphone port 74) held in place with an adhesive fill of the slot. As another alternative, the microphone 72 and its wires 76 could be mold insitu into the concha ring portion 66.

Locating the microphone 72 in the antihelix area has the advantage that it is fairly far from the receiver 44, which reduces the feedback problem. Locating the microphone 72 in the antihelix area also provides good directional performance for the microphone 72, with the natural ear shape reflecting sounds toward the microphone 72 and with the microphone 72 moving with the natural inclination of the wearer's head. Locating the microphone 72 in the antihelix area also hides the microphone 72 somewhat by the antihelix 26 of the ear 16, giving the hearing aid 10 good cosmetic appeal. The microphone 72 could alternatively be located in the electronics portion 40, which would lead to a more secure electrical wiring of the microphone 72 and a simpler assembly process, but would not allow the separation between the microphone 72 and the receiver 44 achieved with the preferred embodiment.

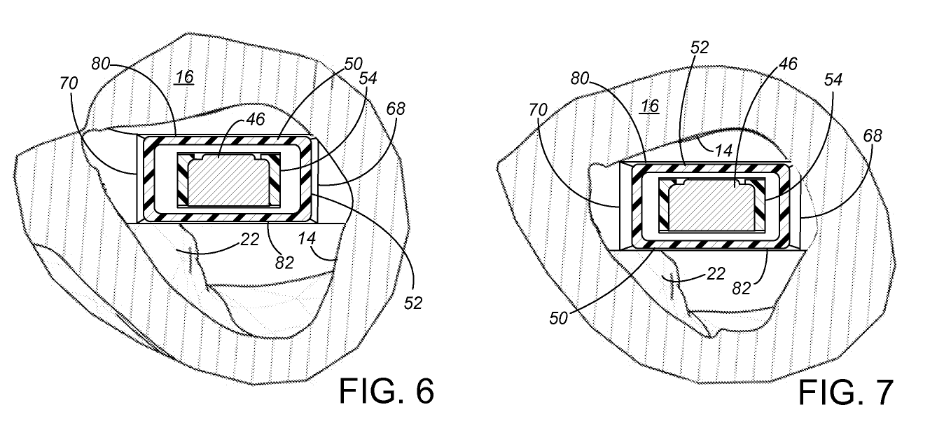

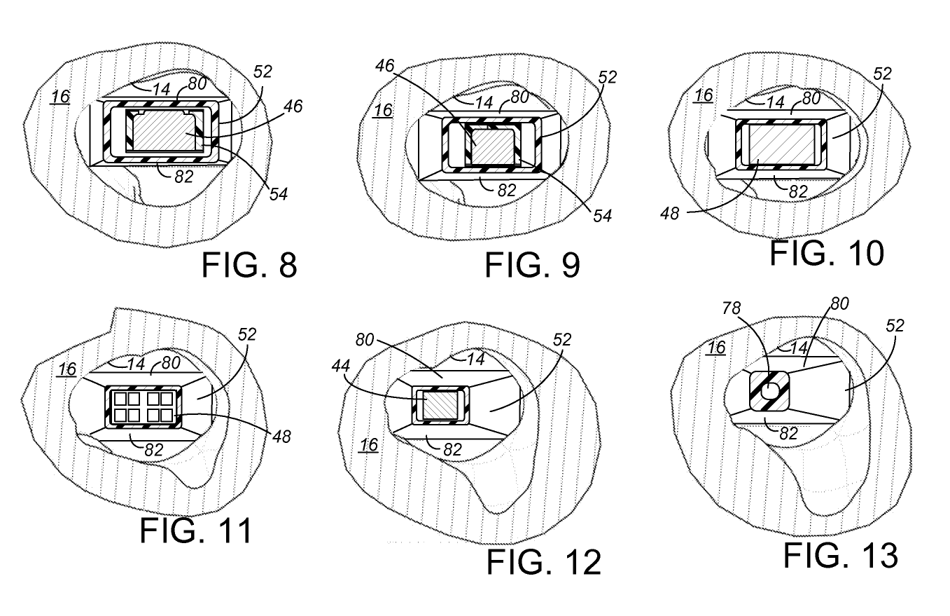

As noted, the hearing aid structure of the present invention is not intended to significantly contact or press into the ear canal wall, best shown with reference to the cross-sectional shapes of FIGS. 6-13, which depict a series of cross-sectional cuts taken generally perpendicular to the axis of the ear canal 14 when the canal portion of the hearing aid 10 is suspended therein. The receiver port 78 is in the ear canal 14, but the distal end of the electronics portion 40 is much smaller than the canal diameter. This results in very minimal contact with the canal wall. The canal portion of the hearing aid 10 primarily includes a concha side face 80 and a tragus side face 82 forming the longer sides of the generally rectangular cross-sectional views, and two faces forming the shorter sides of the generally rectangular cross-sectional views, defining a central axis 84 of the shell 52. The central axis 84 extends at a slight angle (typically 10-20°) to the base plane defined by the tragus contact area 56, the antitragus contact area 58 and the antihelix contact area 60. The primary concern in orienting the shell 52 relative to the suspension portion 42 is for the battery 46 to best fit at the ear canal opening, while extending the receiver 44 into the ear canal 14.

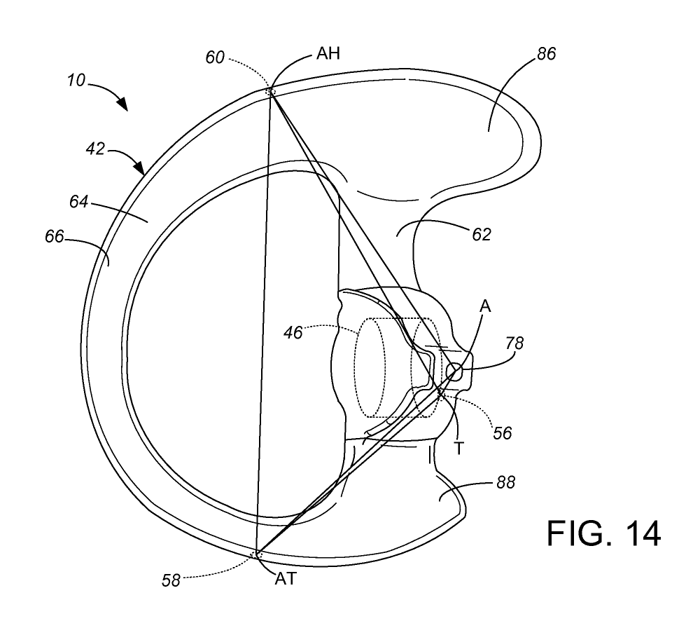

The preferred dimensions of the hearing aid 10 are best described with reference to FIG. 14, which shows a tetrahedron formed by connecting the tragus contact area 56 T, the antitragus contact area AT, the antihelix contact area AH and the apex A of the shell 52 (coinciding with the receiver port 78). When show in this view (with the triangle T-AT-AH being in the plane of the page), the apex A is just outside the contact area. The height or altitude of the apex A relative to the base plane (T-AT-AH contact point plane) is between 5 mm and 25 mm, and more preferably at a height between 10 mm and 15 mm, such that the apex is between ⅓ and ⅔ of the standard depth of most ear canals 14. The preferred altitude of the apex A relative to the base plane is about 13 mm. To provide the stable suspension forces for the suspended apex, each of the tragus contact area T, the antitragus contact area AT and the antihelix contact area AH should be between 10 and 30 mm apart. The distance between the tragus contact area T and the antitragus contact area AT is the shortest of the three distances in the base plane, between 10 mm and 20 mm. In the preferred embodiment, the distance between the tragus contact area T and the antitragus contact area AT is about 14 mm. The distance between the antihelix contact area AH and the antitragus contact area AT is the longest of the three distances in the base plane, between 20 mm and 30 mm. In the preferred embodiment, the distance between the antihelix contact area AH and the antitragus contact area AT is about 26 mm. The distance between the antihelix contact area AH and the tragus contact area T is between 15 mm and 25 mm, with a preferred dimension of about 20 mm. With the preferred altitude of the apex and spacing within the base plane, the distance between the tragus contact area T and the apex A is about 13 mm, the distance between the antitragus contact area AT and the apex A is about 18 mm, and the distance between the antihelix contact area AH and the apex A is about 23 mm. These preferred dimensions provide for the suspension of the apex A within the ear canal 14 as being cantilevered from the base defined by the concha bowl 12.

While there is little variation in shape, there is some variation in the concha size among the human adult population. The generally arcuate rib 64 can bend slightly to accommodate a fairly wide range of concha bowl sizes. Further, the preferred dimensions can easily be modified to fit a wider range of different concha sizes, such as a large version with dimensions 10% greater than the preferred dimensions given and a small version with dimensions 10% smaller than the preferred dimensions given. Another alternative is to design suspension portion 42 with a means to adjust its size. One way to adjust the size of the suspension portion 42 is to create joints in the ring where added length can be inserted, such as in the arcuate rib 64 between the antihelix contact area 60 and the antitragus contact area 58. Another means to adjust the size of the suspension portion 42 is to provide elements attachable to the edges of the ring to increase the dimensions between the tragus contact area 56, the antitragus contact area 58 and the antihelix contact area 60.

The concha side face 80 of the shell 52 does not make significant contact with the ear canal 14, such that skin on concha side of the ear canal 14 continuously flows without contact by the hearing aid 10 to the concha face. The separation distance between the concha side face 80 of the shell 52 and the skin is usually about 2 to 3 mm.

The face of the concha bowl 12 itself is preferably left open and not covered by the suspension portion 42 of the hearing aid 10. The annular opening in the concha ring provides several benefits. By having the annular concha ring, sound is received by the majority of the concha skin surface in a more natural way than most ITE hearing aids which cover the concha face. Because the shell 52 does not fit tightly within the ear canal 14, sound received on the concha skin surface is reflected down the ear canal 14 in a more natural way than possible with most ITC and CIC designs.

In some designs, a fully continuous ring for the suspension portion 42 may not be necessary. However, the preferred suspension structure borrows from the ear plug designs of Surefire LLC to include not only a complete ring, but also a top lobe 86 and a small bottom lobe 88 to more securely hold the suspension structure relative to the concha bowl 12. U.S. Pat. No. 7,394,910 of Surefire LLC is incorporated by reference. Regardless, the important consideration is the layout and relative flexibility of the tragus contact area 56, the antitragus contact area 58 and the antihelix contact area 60, with or without a full ring structure and with or without the top and bottom lobes 86, 88.

The battery compartment is located behind the tragus 24 in the preferred embodiment. The tragus 24 hides the battery 46 somewhat giving an attractive cosmetic look. The exposed surface of the battery door 54 can be colored to match the shadow of the ear canal 14 that is normally seen in this location.

Tests were performed to provide a detailed numerical basis for the comparison between the flexibility of the concha ring/shell structure of the preferred embodiment as compared to prior art hard shell hearing aids. Specifically, the hearing aid 10 was clamped at the shell 52, and a push force was applied at either the antitragus contact area 58 or the antihelix contact area 60. The direction of the push force was in the base plane, toward the center of the suspension portion 42. The push force as a function of deflection on the preferred embodiment was as follows:

TABLE I
PUSH IN AT ANTITRAGUS CONTACT AREA

| deflection (mm) | Force (mN) | Stiffness (N/m) |
|---|---|---|
| 0.0 | 0 | |
| 0.5 | 65 | 130 |
| 1.0 | 110 | 110 |
| 1.5 | 150 | 100 |

TABLE II
PUSH IN AT ANTIHELIX CONTACT AREA

| deflection (mm) | Force (mN) | Stiffness (N/m) |
|---|---|---|
| 0.0 | 0 | |
| 0.5 | 70 | 140 |
| 1.0 | 120 | 120 |
| 1.5 | 170 | 110 |
| 2.0 | 200 | 100 |

It can thus be seen that the hearing aid 10 can be readily adapted over a fairly wide range of concha sizes and structure, but without generating uncomfortable forces on the concha 12 of the wearer. In contrast, a prior art hard shell hearing aid responded to a push test (a HANSATON hearing aid with the other side of the hearing aid clamped) as follows:

TABLE III
PRIOR ART PUSH TEST

| deflection (mm) | Force (mN) | Stiffness (N/m) |
|---|---|---|
| 0.0 | 0 | |
| 0.2 | 400 | 2000 |
| 0.3 | 500 | 1600 |
| 0.4 | 650 | 1600 |
| 0.5 | 800 | 1600 |

The present invention has a flexibility in excess of ten times that of a hard plastic shell.

The present invention was further push tested by clamping the antitragus and antihelix contact areas 58, 60, and applying a horizontal (generally perpendicular to the central axis 84) and a vertical (generally in line with the central axis 84) force to the apex A of the shell 52, with results shown in Tables IV and V below:

TABLE III
PUSH VERTICAL AT APEX

| deflection (mm) | Force (mN) | Stiffness (N/m) |
|---|---|---|
| 0.0 | 0 | |
| 1.0 | 90 | 90 |
| 1.5 | 120 | 80 |

TABLE IV
PUSH HORIZONTAL AT APEX

| deflection (mm) | Force (mN) | Stiffness (N/m) |
|---|---|---|
| 0.0 | 0 | |
| 3.0 | 35 | 12 |
| 4.0 | 38 | 10 |
| 5.0 | 41 | 8 |

It can thus be seen that the present invention, even if coming in contact with the ear canal 14 (such as often happens during insertion of the hearing aid 10 into the ear 16, but also could happen if not properly aligned with the ear 16 or if the shape of the wearer's ear canal 14 were drastic out of norm), will only place a minimal force on the tissue of the ear canal 14. Even though the shell 52 is formed of the same material as prior art shells, the relative flexibility of the apex A of the hearing aid 10 is on the order of 100 times greater than in the prior art design.

As a further basis for comparison, horizontal and vertical apex push tests were taken of a prior art “soft tip” design, specifically of a UNITRON FUSE hearing aid, with the following results:

TABLE V
PRIOR ART PUSH VERTICAL AT APEX

| Deflection (mm) | Force (mN) | Stiffness (N/m) |
|---|---|---|
| 0.0 | 0 | |
| 0.5 | 155 | 310 |
| 1.0 | 285 | 285 |

TABLE VI
PRIOR ART PUSH HORIZONTAL AT APEX

| deflection (mm) | Force (mN) | Stiffness (N/m) |
|---|---|---|
| 0.0 | 0 | |
| 0.5 | 160 | 320 |
| 1.0 | 300 | 300 |

The UNITRON FUSE hearing aid is a CIC design, which is intended to flex with the natural movement of the wearer's ear canal 14. Again, even if/when the apex comes into contact with the ear canal 14, the present invention is substantially more flexible over the length of the device even than prior art soft tip designs.

The concha ring design of this hearing aid 10 is thus more comfortable than traditional designs that are held into place by contact with the ear canal 14. The concha bowl 12 has much less variation in shape than ear canals 14, and the concha bowl 12 is more tolerant of pressure points than the ear canal 14.

The concha ring design is also easy and intuitive for the user to put into place. The concha ring structure 66 is relatively easy to grasp and makes it relatively easy for the user's fingers to manipulate the location and orientation of the hearing aid 10 when inserting the hearing aid 10 into the user's ear 16. The concha ring structure 66 is also relatively easy for the user to grab when the user's desires to remove the hearing aid 10 from his or her ear. The concha ring structure 66 leads to a very consistent positioning of the hearing aid 10 relative to the user's ear 16 over multitudes of insertions and removals, leading to a more consistent performance of the hearing aid 10.

Although the present invention has been described with reference to preferred embodiments, workers skilled in the art will recognize that changes may be made in form and detail without departing from the spirit and scope of the invention. For instance, the electronics housing portion 50 could be formed integrally with the suspension portion 42, with the electrical components molded into the material of the suspension portion 42. With current manufacturing conditions, forming the electronics housing portion 50 with a hard shell 52 permits a face plate assembly process well known and used in the hearing aid industry, with the hard shell 52 of the electronics housing portion 50 containing and protecting the sensitive electrical connections between the electrical components. The electronics housing portion 50 also allows the battery 46 to be housed with a moving battery door 54, which enables user-replacement of the battery 46 in a well known manner and with the battery door 54 concealing the battery 46 during use of the aid 10. However, the suspension concepts of the present invention could be equally applied even if the hearing aid housing was formed of a single material with sufficient flexibility.

What is claimed is:

1. A hearing aid comprising:
a ring housing portion having three areas of contact, such that the ring housing portion can held in place in a user's ear by contact with three main points of concha anatomy, the ring housing portion having substantial flexibility between the three areas of contact;
a canal housing portion attached to and extending from the ring housing portion to be received in the user's ear canal, the canal housing portion being smaller than the canal dimensions so as to have minimal contact with the canal wall;
a receiver positioned within the canal housing portion such that the receiver is substantially cantilevered in a suspended position within the user's ear canal with forces from the ring housing portion; and
a microphone positioned within either the ring housing portion or the canal housing portion;
a hearing aid amplifier positioned within either the ring housing portion or the canal housing portion, the hearing aid amplifier receiving a signal from the microphone and electrically driving the receiver.

2. The hearing aid of claim 1, wherein the ring housing portion is adjustable in size.

3. The hearing aid of claim 1, wherein the ring housing portion forms a complete circle defining a central concha opening for exposing a central portion of the user's concha.

4. The hearing aid of claim 1, wherein the ring housing portion is formed of a translucent material.

5. The hearing aid of claim 4, wherein the microphone is positioned within an anti-helix shadow area of the ring housing portion.

6. The hearing aid of claim 1, wherein the ring housing portion is formed of a different material than the canal housing portion.

7. The hearing aid of claim 1, wherein the ring housing portion is formed of a rubbery material having a durometer of less than about 90 on the Shore A scale, and wherein the canal housing portion is formed of a plastic material having a durometer of greater than about 50 on the Shore D scale.

8. The hearing aid of claim 1, wherein the three areas of contact of the ring housing portion define a contact base plane, and wherein the receiver is positioned within the canal housing portion so as to be suspended at a depth of between 5 and 25 mm inches from the contact base plane.

9. The hearing aid of claim 1, wherein the three areas of contact of the ring housing portion define a contact base plane, wherein the receiver is positioned within the canal housing portion so as to be suspended at a distance of between 5 and 25 mm from the contact base plane, suspended as the apex of a pyramid with the apex outside the plan view of a triangle formed by the three areas of contact.

10. The hearing aid of claim 1, wherein the three areas of contact comprise a tragus contact area, an antitragus contact area and an anti-helix contact area, wherein the ring housing portion has a central concha opening for exposing a central portion of the user's concha.

11. The hearing aid of claim 10, wherein the distance between the tragus contact area and the antitragus contact area is between 10 mm and 20 mm, wherein the distance between the antihelix contact area and the antitragus contact area is between 20 mm and 30 mm, and wherein the distance between the antihelix contact area and the tragus contact area is between 15 mm and 25 mm.

12. The hearing aid of claim 1, further comprising a battery compartment within the canal housing portion.

13. The hearing aid of claim 12, wherein the hearing aid amplifier is a digital signal processor chip positioned within the canal housing portion between the battery compartment and the receiver.

14. The hearing aid of claim 1, wherein the microphone is positioned within the ring housing portion.

15. The hearing aid of claim 14, further comprising wires for the microphone positioned within a slit in the ring housing portion.

16. A hearing aid comprising:
a ring housing portion sized to be held in place in a wearer's concha bowl, the ring housing portion defining an annulus exposing skin of the wearer's concha bowl therethrough, the ring housing portion being formed of a first material which is rubbery so as to provide substantial flexibility;
a canal housing portion attached to and extending from the ring housing portion to be received in the user's ear canal, the canal housing portion being formed of a second, substantially rigid material;
a receiver positioned within the canal housing portion;
a microphone positioned within either the ring housing portion or the canal housing portion; and
a hearing aid amplifier positioned within either the ring housing portion or the canal housing portion, the hearing aid amplifier receiving a signal from the microphone and electrically driving the receiver.

17. The hearing aid of claim 16, wherein the ring housing portion provides a stiffness of 200 N/m or less over the first millimeter of deflection and wherein the canal housing portion provides a stiffness of 1000 N/m or more over the first 0.5 mm of deflection.

18. A process of making a hearing aid comprising:
forming a ring housing portion to be received in a user's ear concha;
forming a canal housing portion separately from the ring housing portion, the canal housing portion to be received in the user's ear canal
assembling electronics including at least a microphone into the ring housing portion;
assembling electronics including at least a receiver into the canal housing portion; and
joining the ring housing portion to the canal housing portion, such that the ring housing portion and the canal housing portion jointly have three areas of contact and can held in place in a user's ear by contact with three main points of concha anatomy, with the ring housing providing substantial flexibility between the three areas of contact.

19. The process of claim 18, wherein the electronics comprises wires, and further comprising:
slitting the ring housing portion;
inserting wires into the slit.

20. The process of claim 18, further comprising:
assembling a digital signal processor chip into the canal housing portion;
and wherein the canal housing portion is formed with a battery compartment.
